(19) United States
(12) Patent Application Publication
(10) Pub. No.: US 2004/0237882 A1
(43) Pub. Date: Dec. 2, 2004

(54) Method of manufacturing potassium niobate single crystal thin film, surface acoustic wave element, frequency filter, frequency oscillator, electronic circuit, and electronic apparatus

(76) Inventors: Takamitsu Higuchi, Matsumoto-shi (JP); Katsuyuki Morii, Suwa-shi (JP); Setsuya Iwashita, Nirasaki-shi (JP); Hiromu Miyazawa, Nagano-ken (JP)

Correspondence Address: HARNESS, DICKEY & PIERCE, P.L.C., P.O. BOX 828, BLOOMFIELD HILLS, MI, 48303, US

(21) Appl. No.: 10/808,250

(22) Filed: Mar. 24, 2004

(30) Foreign Application Priority Data
Mar. 26, 2003 (JP) 2003-085761

(51) Int. Cl. C30B 23/00; C30B 25/00; C30B 28/12; C30B 28/14

(52) U.S. Cl. 117/95

(57) ABSTRACT

A method of manufacturing potassium niobate single crystal thin film on a single crystal substrate that epitaxially grows orthorhombic potassium niobate single crystal at a temperature near room temperature at a high deposition rate. A surface acoustic wave element, frequency filter, frequency oscillator, electronics circuit, and electronic device employ the thin film manufactured by the method, and are high in k², wideband, downsized, and economical in power consumption. The method includes the steps of coating liquid drops of a potassium niobate solution on a SrTiO₃ single crystal substrate by a liquid drop emission method, and precipitating potassium niobate single crystal layer by epitaxial growth from the liquid drops.

### PRIORITY CLAIM

Priority is claimed on Japanese Patent Application No. 2003-85761, filed Mar. 26, 2003, the content of which is incorporated herein by reference.

### BACKGROUND OF THE INVENTION

1. Field of the Invention

The present invention relates to a method of manufacturing potassium niobate single crystal thin film, and to a surface acoustic wave element, a frequency filter, a frequency oscillator, an electronic circuit, and an electronic apparatus, each having the potassium niobate single crystal thin film.

2. Description of Related Art

There has been a remarkable expansion in the demand for surface acoustic wave elements with rapid developments in telecommunications centered on mobile communication, which is typified by mobile telephones. Some trends in the development of surface acoustic wave elements include size reduction, increasing efficiency, and increasingly higher frequencies, as in mobile telephones. In order to attain these, a larger electromechanical coupling coefficient (k² hereinbelow) and a higher surface acoustic wave propagation velocity become necessary. For example, when used as a high frequency filter, a high k² is desirable in order to obtain a small loss and a wide bandwidth. In order to make the resonance frequency a high frequency, a material having a higher acoustic velocity is desirable in view of the limits of the design rules for the pitch of inter-digital transducers (IDT hereinbelow). Furthermore, in order to stabilize the characteristics of the temperature range in which surface acoustic wave elements are used, the center frequency temperature coefficient (TCF) must be small.

Conventionally, surface acoustic wave elements generally have a structure in which an IDT is formed on a single crystal piezoelectric body. Representative piezoelectric single crystals are those of quartz, lithium niobate (LiNbO₃ hereinbelow), lithium tantalite (LiTaO₃ hereinbelow), and the like. For example, in an RF filter requiring a broad band and low loss in the pass band, LiNbO₃, which has a large k², is used. In contrast, in an IF filter requiring stable temperature characteristics even in a narrow band, quartz, which has a small TCF, is used. Furthermore, LiTaO₃ plays an intermediate role because its k² and TCF are each between those of LiNbO₃ and quartz. However, even for LiTaO₃, which has the highest k², the k² is about 20%.

Recently, a cut angle that exhibits a large k² value has been discovered in potassium niobate (KNbO₃ hereinbelow) single crystal (a=0.5695 nm, b=0.5721 nm, c=0.3973 nm; below, the orthorhombic crystal is represented by these indices). As reported in Electron. Lett. Vol. 33 (1997) 193, it can be predicted by calculation that a 0° Y-cut X-propagation (hereinbelow, 0° Y-X) KNbO₃ single crystal plate shows an extremely high value of k²=53%. Furthermore, as reported in Jpn. J. Appl. Phys. Vol. 37 (1998) 2929, it has been experimentally confirmed that a 0° Y-X KNbO₃ single crystal plate demonstrates a high value of k² (about 50%), and it is reported that the oscillation frequency of the filter using the Y-X KNbO₃ single crystal plate rotated from 45° to 75° demonstrates zero temperature properties at room temperature. Published Japanese Patent Application No. Hei 10-65488 discloses that the single crystal plates are used as a surface acoustic wave substrate.

In surface acoustic wave elements that use a piezoelectric single crystal substrate, characteristics such as k², the temperature coefficient, sound velocity and the like are values intrinsic to the material, and are determined by the cut angle and the propagation direction. A 0° Y-X KNbO₃ single crystal substrate has a superior k², but the zero temperature properties like those of the Y-X KNbO₃ single crystal substrate rotated from 45° to 75° are not exhibited at room temperature. In addition, the propagation velocity is low in comparison to strontium titanate (SrTiO₃ hereinbelow) and calcium titanate (CaTiO₃ hereinbelow), which are also perovskite-type oxides. Thus, when only a KNbO₃ single crystal substrate is used, the sound velocity, high k², and zero temperature properties cannot all be satisfied.

Thus, a piezoelectric thin film is laminated on some type of substrate, film thickness is controlled, and it is thereby anticipated that the sound velocity, k², and temperature characteristics will be improved. Examples include a zinc oxide (ZnO hereinbelow) thin film formed on a sapphire substrate, as reported in Jpn. J. Appl. Phys. Vol 32 (1993) 2337, or a LiNbO₃ thin film formed on a sapphire substrate, as reported in Jpn. J. Appl. Phys. Vol. 32 (1993) L745. Therefore, for KNbO₃ as well, it is anticipated that all properties will be improved by depositing a thin film onto a substrate. It is preferable that the piezoelectric thin film be oriented in an optimal direction in order to exhibit its k² and temperature characteristics, and it is preferable that it be a flat, compact epitaxial film in order to minimize as much as possible the loss that accompanies leaky wave propagation. Here, a Y-X KNbO₃ thin film having a k² of about 50% corresponds to the pseudo-cubic crystal (100), and the 90° Y-X KNbO₃ thin film having a k² of 10% corresponds to the pseudo-cubic crystal (110). Therefore, for example, by using a SrTiO₃(100) or (110) single crystal substrate, it is possible to obtain a Y-X KNbO₃ thin film having a k² of about 50% or a 90° Y-X KNbO₃ thin film having a k² of about 10%.

In the case of forming films by a conventional thin film forming process such as conventional vapor deposition or sol-gel process, at least 500° C. was required, which applied to perovskite-type oxides, as a film forming temperature or a heat treatment temperature after film forming. However, although KNbO₃ was orthorhombic at a room temperature, it had an orthorhombic-tetragonal transition temperature at 225° C. and a tetragonal-cubic transition temperature at 435° C. Therefore, in the process of cooling from a film forming temperature, phase transitions had occurred from cubic to tetragonal and orthorhombic. In particular, at the time of phase transition from tetragonal to orthorhombic, the twins were easily formed that rendered coexistent the orthorhombic directions of an a axis and a b axis so that stress in the crystal might be reduced, and manufacturing a single crystal with a single domain was difficult.

In order to solve the problem and manufacture a single domain single crystal, film forming temperature should be kept below 225° C. which is the phase transition temperature from orthorhombic to tetragonal. Accordingly, a precipitation method has been proposed that precipitates KNbO₃ crystal from a solution of niobium and potassium at a low temperature. The method, according to Jpn. J. Appl. Phys., vol. 40 (2001) 5657, heats a solution of potassium niobate fluoride at about 100° C. to evaporate water to precipitate crystal powder of orthorhombic KNbO₃ with a size of about 10 μm.

However, since the conventional method for manufacturing single crystal thin film described above took some time to evaporate the water, time change rate of solute supersaturation was small. It was difficult to control the starting point of nucleation of crystal growth. Accordingly, there was a problem in that thin film could not be formed at a high deposition rate.

The invention was made to solve the problem described above. That is, the invention provides a method for manufacturing KNbO₃ single crystal thin film, by which orthorhombic KNbO₃ single crystal thin film can be formed on a substrate based on epitaxial growth at a high deposition rates at a low temperature. In addition, by the use of the thin film obtained by the method, the invention provides a surface acoustic wave element having a large k² suitable for a wide band, a small size and a lower power consumption, which can be used in a frequency filter, a frequency oscillator, an electronic circuit, and an electronic apparatus.

### SUMMARY OF THE INVENTION

The invention takes the following measures to solve the problems above. A method of manufacturing potassium niobate single crystal thin film in accordance with the invention comprises the steps of coating liquid drops of a potassium niobate solution on a substrate and precipitating orthorhombic potassium niobate single crystal from the liquid drops. According to the method, since orthorhombic potassium niobate single crystal is precipitated from the liquid drops at a low temperature such as room temperature, for example, in an atmospheric pressure, film forming time can be reduced. A surface acoustic wave element excellent in k² can be produced at a low cost, using the potassium niobate single crystal thin film obtained.

Preferably, in the method of the invention, the step of coating liquid drops is carried out by a liquid drop emission method. According to this, a predetermined volume of liquid drops can be coated at a desired position on the substrate. Especially when the volume of the liquid drop is less than 100 picoliter, a solvent tends to evaporate after coating, which can increase the rate of change of supersaturation of a solute with respect to time. In addition, since the coating positions for the liquid drops can be controlled continuously, a desired area of thin film is formed. Therefore, as mentioned above, a surface acoustic wave element having excellent k² can be produced at a low cost.

Preferably, in the invention, the coating step and the precipitating step are carried out repeatedly, and the coating is carried out so that the liquid drops to be coated in a subsequent step may be overlapped with at least a part of the orthorhombic potassium niobate single crystal precipitated in the previous precipitating step. According to the method, new single crystals can be precipitated one after another following a previously precipitated single crystal, which leads to forming a large area of single crystal thin films. Moreover, as mentioned above, a surface acoustic wave element having excellent k² can be produced at a low cost.

Advantageously, in the invention, the potassium niobate solution is a potassium niobate fluoride aqueous solution. In accordance with the invention, since the aqueous solution is used, the speed of moisture evaporation from the liquid drops is high near room temperature, which can bring about a big change in solute density over time and manufacture a single crystal thin film at a high deposition rate. Owing to that, a surface acoustic wave element having excellent k² can be produced at a low cost.

Advantageously, in the invention, the substrate has an axis on a surface thereof that is oriented in a direction perpendicular and in-plane to the surface, and the potassium niobate single crystal is epitaxially grown on the substrate. According to the method, since a crystal is precipitated along orientation on the substrate, it is possible to form a potassium niobate single crystal thin film having a uniform orientation over the entire thin film. A surface acoustic wave element having excellent k² can be produced at a low cost.

Preferably, in the invention, the substrate is strontium titanate (100) single crystal substrate. According to the method, the use of strontium titanate single crystal substrate, which is a perovskite-type oxide single crystal substrate, forms potassium niobate single crystal thin film on the substrate at a low cost and produces a surface acoustic wave element having excellent k² at a low cost.

Preferably, in the invention, the substrate comprises a silicon single crystal substrate and a buffer layer epitaxially grown thereon. According to the method, since the buffer layer is provided on the silicon single crystal substrate, even an inexpensive silicon single crystal substrate can be used to precipitate potassium niobate single crystal and as a result form a potassium niobate single crystal thin film, which eventually produces a surface acoustic wave element having excellent k² at a low cost.

Preferably, in the invention, the buffer layer includes a first buffer layer having a NaCl-type oxide and a second buffer layer having a simple perovskite-type oxide epitaxially grown thereon. Advantageously, the buffer layer includes a fluorite-type oxide first buffer layer, and a second buffer layer that contains a layered perovskite-type oxide epitaxially grown on the first buffer and a simple perovskite-type oxide epitaxially grown on the perovskite-type oxide. According to the method, since between the silicon simple crystal and the potassium niobate single crystal, there is formed a buffer layer favorable to both, the potassium niobate single crystal is formed on the inexpensive silicon single crystal substrate. A surface acoustic wave element having excellent k² can therefore be produced at a low cost.

Preferably, in the invention, the substrate includes one of a crystal, quartz, SiO₂ covered silicon, and diamond-covered silicon, and a buffer layer formed thereon, and wherein the buffer layer includes a first buffer layer grown on the substrate in in-plane orientation independently of crystal orientation of a surface of the substrate and a second buffer layer having oxide epitaxially grown thereon, the first and second buffer layers manufactured by a vapor deposition method accompanying ion beam illumination. According to the method, the high quality potassium niobate single crystal thin film is manufactured at a low cost even on a substrate comprising a crystal, quartz, SiO₂ covered silicon, or diamond-covered silicon suitable for a surface acoustic wave element, and a surface acoustic wave element having excellent k² can be produced at a low cost.

Preferably, in the invention, the first buffer layer is manufactured of a NaCl-type oxide, and the second buffer layer is manufactured of a simple perovskitte-type oxide. Also preferably, in the invention, the first buffer layer is manufactured of a fluorite-type oxide, and wherein the second buffer layer is manufactured of a layered perovskite-type oxide and a simple perovskitte-type oxide grown epitaxially thereon. According to the method, a high quality potassium niobate single crystal thin film is manufactured at a low cost even on a substrate of inexpensive crystal, quartz, SiO₂ covered silicon, or diamond-covered silicon, and a surface acoustic wave element having excellent k² can be produced at a low cost.

A surface acoustic wave element of the invention comprises a potassium niobate single crystal thin film produced by the manufacturing method of the invention. Since the surface acoustic wave element comprises a potassium niobate single crystal thin film having a large electromechanical coupling coefficient, small and inexpensive surface acoustic wave elements can be realized.

A frequency filter of the invention comprises a surface acoustic wave element of the invention. A frequency oscillator of the invention comprises a surface acoustic wave element of the invention. The frequency filter and frequency oscillator in accordance with the invention are small and inexpensive, and can realize a filter of wide band.

An electronic circuit of the invention comprises a frequency oscillator of the invention. The frequency oscillator has a filter of wide band, and being small and inexpensive, contributes to reducing power consumption. An electronic apparatus of the invention comprises at least one of a frequency filter, a frequency oscillator, and an electronic circuit, all of which are directed to the invention. The electronic apparatus provides a downsizing, powersaving, and wideband system.

### BRIEF DESCRIPTION OF THE DRAWINGS

FIG. 1 is a cross-sectional view of a KNbO₃ thin film in the first embodiment.

FIG. 2 is a perspective view of a liquid drop emission apparatus for the first embodiment.

FIGS. 3A and 3B show a structure of an emission head for the liquid drop emission apparatus shown in FIG. 2.

FIG. 4 is a cross-sectional view of a surface acoustic wave element of the first embodiment.

FIG. 5 is a cross-sectional view of KNbO₃ thin film in the second embodiment.

FIG. 6 is a perspective view of a deposition apparatus for the second embodiment.

FIG. 7 is a cross-sectional view of a surface acoustic wave element of the second embodiment.

FIG. 8 is a cross-sectional view of KNbO₃ thin film in the third embodiment.

FIG. 9 is a cross-sectional view of a surface acoustic wave element of the third embodiment.

FIG. 10 is a perspective view of a frequency filter of the embodiment in accordance with the invention.

FIG. 11 is a perspective view of a frequency oscillator of the embodiment in accordance with the invention.

FIGS. 12A and 12B are a perspective view of a frequency oscillator of the embodiment in accordance with the invention.

FIG. 13 is a block diagram showing a PLL circuit of the embodiment in accordance with the invention.

FIG. 14 is a block diagram showing an electronic circuit of the embodiment in accordance with the invention.

FIG. 15 is a perspective view of a cellular phone of the embodiment in accordance with the invention.

### DETAILED DESCRIPTION OF THE INVENTION

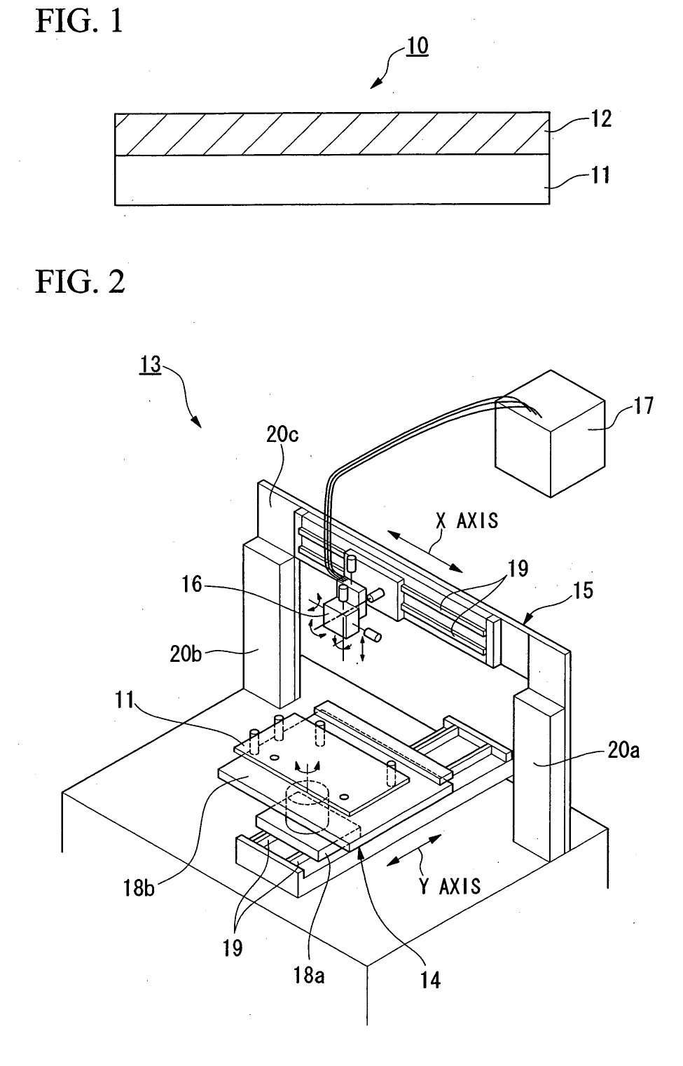

The first embodiment of the invention will be discussed referring to FIGS. 1-4. FIG. 1 is a cross-sectional view of KNbO₃ thin film in the first embodiment. A potassium niobate (KNbO₃) single crystal thin film 10 in accordance with the invention comprises a strontium titanate (SrTiO₃) single crystal substrate 11 and a KNbO₃ single crystal layer 12 grown epitaxially thereon. The SrTiO₃ single crystal substrate 11 includes a crystal axis having a (100) orientation normal to and a (001) orientation parallel to the substrate surface.

FIG. 2 is a perspective view of a liquid drop emission apparatus for the first embodiment. The liquid drop emission apparatus 13, which is used for forming the KNbO₃ single crystal thin film 10 in a liquid drop emission method, comprises a substrate movement mechanism 14, a head movement mechanism 15, an emission head 16, and a reservoir 17. The substrate movement mechanism 14 includes a slider 18a, a table 18b mounted thereon and a guide rail 19 for moving the slider 18a along the Y axis. For example, a linear motor (not shown) moves the slider 18a on the guide rail 19. On the table 18b is placed the SrTiO₃ single crystal substrate 11. The head movement mechanism 15 contains a pair of frames 20a and 20b, and a traveling lane 20c provided thereon. The traveling lane 20c is placed in the direction of the X axis, that is, orthogonal to the direction of the Y axis of the substrate movement mechanism 14, and moves the emission head 16 to the X axis direction, for example, by a linear motor (not shown).

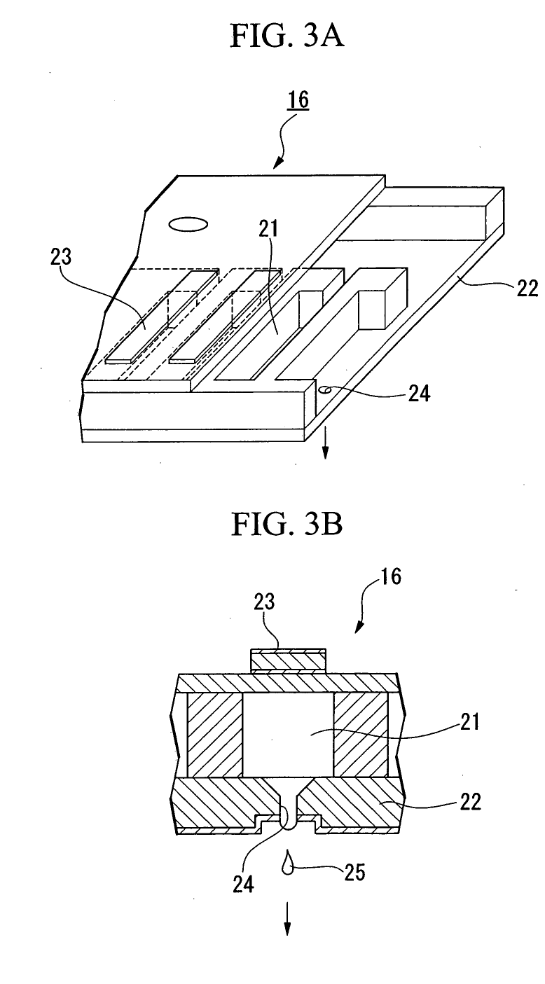

FIGS. 3A and 3B show a structure of an emission head for the liquid drop emission apparatus. The emission head 16 includes a cavity 21, a nozzle plate 22, and an emission mechanism 23. The cavity 21 is filled with liquid for coating, and a plurality of the opening-type nozzles, aligned horizontally and vertically, for emitting liquid drops from the cavity 21 are formed on the nozzle plate 22. The emission mechanism 23, comprising piezoelectric elements, is driven by a power supply (not shown), which emits the liquid in the cavity 21 through the nozzles 24. The emission mechanism 23 and the nozzles 24 are adjusted to emit an amount of less than 100 picoliters per emission, preferably less than 20 picoliters. The reservoir 17 holds the liquid for coating inside, communicating with the cavity 21 of the emission head 16.

The method of manufacturing the KNbO₃ single crystal thin film 10 of the embodiment in accordance with the invention will be explained. The manufacturing method comprises the step of coating liquid drops of the solution including KNbO₃ on the SrTiO₃ single crystal substrate 11 by a liquid emission method, and precipitating orthorhombic KNbO₃ single crystal from the coated liquid drops based through epitaxial growth. The manufacturing process will be explained below.

First, prior to the coating step, some material is prepared. The powder of each of potassium carbonate (K₂CO₃) and niobium oxide (Nb₂CO₅) is mixed at the mol ratio K:Nb=1:1, which is baked for 12 hours at 1000° C. in the air to adjust the material powder of KNbO₃. The obtained KNbO₃ material powder is further pulverized. And then powder of potassium fluoride (KF) is mixed at the mol ratio of 1:1, and potassium niobate fluoride (K₂NbO₃F) is obtained after 12-hour baking at 700° C.

Next, an aqueous solution of K₂NbO₃ 25 is prepared. The pulverized K₂NbO₃F powder is weighed and poured into pure water heated at 80° C. to make a solution concentration of about 1 wt %. The solution is stirred to melt the powder over about 24 hours by, for example, a magnetic stirrer to produce a transparent aqueous solution of K₂NbO₃F 25 close to saturation concentration. The requirements of melting temperature, time, etc., are not limited to the ones shown above. Specifically, the concentration may be supersaturated. The K₂NbO₃F water solution 25 is kept in the reservoir 17 of the liquid drop emission apparatus 13 shown in FIG. 2.

Next, the SrTiO₃ single crystal substrate 11 is prepared. After the SrTiO₃ single crystal substrate 11 is immersed in an organic solvent, an ultrasonic cleaning apparatus is used for degreasing and cleaning. As an organic solvent, for example, a mixed liquid of ethyl alcohol and acetone at the ratio of 1:1 can be used. However, the present invention is not limited to the mixed liquid. The SrTiO₃ single crystal substrate 11 is placed on the table 18b of the liquid drop emission apparatus 13 shown in FIG. 2.

The coating process for coating the liquid drop of the K₂NbO₃F water solution 25 on the SrTiO₃ single crystal substrate 11 by the liquid drop emission method will be discussed below. By operating the substrate movement mechanism 14 and the head movement mechanism 15, the emission head 16 and the SrTiO₃ single crystal substrate 11 are moved to a desired home position, respectively, where they are faced to each other. Then, the K₂NbO₃F water solution 25 in the reservoir 17 is supplied to the cavity 21. After the cavity 21 is filled, liquid drops of the K₂NbO₃F water solution 25 are discharged, with the emission mechanism 23 driven, from the nozzle 24 to the surface of the SrTiO₃ single crystal substrate 11. Thus, the K₂NbO₃F water solution 25 is coated on the SrTiO₃ single crystal substrate 11.

Next, the precipitating process for precipitating orthorhombic KNbO₃ single crystal is explained below. When the discharged liquid drops, the volume of each of which is small, that is, less than 20 picoliter, are attached on the surface of the SrTiO₃ single crystal substrate 11, the moisture of the K₂NbO₃F water solution 25 is likely to evaporate at such a low temperature as room temperature to initiate precipitating of single crystal. In this way, with the SrTiO₃ single crystal as a seed crystal, orthorhombic KNbO₃ single crystal of the (110) orientation in the vertical direction of a film surface and the (001) orientation within the film surface is grown epitaxially.

The coating process and precipitating process are performed repeatedly. The emission head 16 is moved by the head movement mechanism 15, when driven, to a position for coating, where the liquid drops of the K₂NbO₃F water solution 25 to be coated in the subsequent coating process can overlap at least part of orthorhombic KNbO₃ single crystal precipitated in the previous precipitating process. Then, with the emission mechanism 23 driven, the liquid drops of the K₂NbO₃F water solution 25 are discharged from the nozzle 24 to the surface of the SrTiO₃ single crystal substrate 11. In this way, in the direction of the X axis on the surface of the SrTiO₃ single crystal substrate 11, a KNbO₃ single crystal layer 12 is precipitated continuously.

Then, the substrate movement mechanism 14 is driven to move the SrTiO₃ single crystal substrate 11 to the Y axis direction. By repeating the above coating and precipitating processes, the KNbO₃ single crystal layer 12 is precipitated on the entire surface of the SrTiO₃ single crystal substrate 11. The same procedure is used to achieve a desired thickness. Thus, when KNbO₃ and SrTiO₃ are represented by orthorhombic or crystal indices, respectively, KNbO₃ single crystal thin film 10 having the orientation relationship KNbO₃ (110)/SrTiO₃ (100) in the direction perpendicular to the film surface and KNbO₃<001>//SrTiO₃<001> in the direction parallel to the film surface is formed.

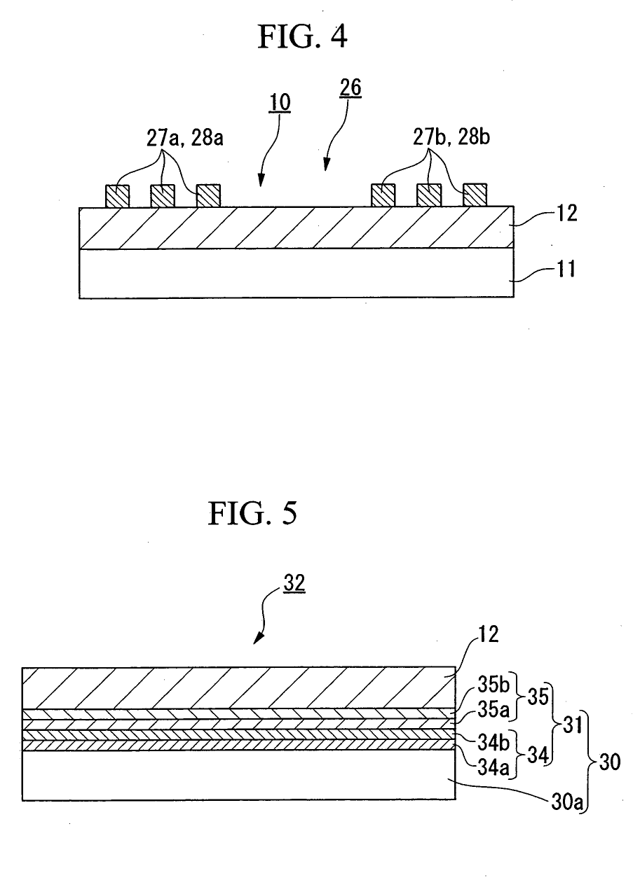

FIG. 4 is a cross-sectional view of a surface acoustic wave element 26 in the first embodiment. The surface acoustic wave element 26 will be explained below. The surface acoustic wave element 26, as shown in FIG. 4, includes the KNbO₃ single crystal thin film 10 explained above. A method of making the surface acoustic wave element 26 will be explained below. First, by vacuum evaporation using aluminum metal (Al), a pair of aluminum electrodes 27a, 27b is deposited on the KNbO₃ single crystal thin film 10 on the condition that the degree of vacuum is 6.65×10⁻⁵ Pa (5×10⁻⁷ Torr) and the substrate temperature is 45° C. The temperature of the substrate, the degree of vacuum, and the ratio of argon to oxygen are not limited to these. Next, the continuous processes, which comprises resist coating, exposure, dry etching, and patterning process by removing resist, are performed on the aluminum electrodes 27a and 27b to form a pair of IDTs 28a and 28b. In this way, the surface acoustic wave element 26 is manufactured.

With respect to the surface acoustic wave element 26 manufactured, a sound speed, which is obtained from delay time Vₒₚₑₙ of a train of surface acoustic waves traveling between 28a and 28b of the IDT, is 4000 m/s. The value k², obtained from the difference between delay time Vₒₚₑₙ and delay time Vₛₕₒᵣₜ of a train of surface acoustic waves when the space between 28a and 28b of the IDT is covered with metal thin film, is 25%. Since the value k², obtained at the time when the KNbO₃ single crystal thin film is manufactured at a high temperature by a vapor deposition method, is also 25%, a sufficiently large value of k² is obtained even by a liquid drop method.

In the above precipitating process, the moisture in the liquid drops of the K₂NbO₃F water solution 25 is evaporated by natural drying under atmospheric pressure. To increase precipitating speed, precipitation can be performed under a reduced pressure atmosphere. The table 18b is kept at normal temperature; however, it can be heated to higher temperature than room temperature to increase precipitating speed. In replace of the potassium niobate solution, an aqueous solution of potassium sodium niobate tantalate fluoride (K₁₋ₓNaₓ)₂(Nb_{1-y}Ta_{y})O₃F(0≦x≦1, 0≦y≦1) can be used to produce a solid solution thin film of K₁₋ₓNaₓNb_{1-y}O₃ (0≦x≦1, 0≦y≦1).

According to the method of producing KNbO₃ single crystal thin film, microscopic liquid drops of the K₂NbO₃F water solution 25, coated on the SrTiO₃ single crystal substrate 11, may be used as a base for nucleus generation. Since the moisture of the water solution evaporates soon after coating, the change rate with respect to time for the degree of supersaturation of the solute can be increased and a KNbO₃ single crystal layer 12 is precipitated at a high deposition rate for epitaxial growth. In addition, since coating positions for liquid drops can be controlled continuously, a desired area and/or thickness of the KNbO₃ single crystal thin film 10 can be made. As a result, surface acoustic wave elements having excellent k² can be manufacture at a low cost.

The second embodiment in accordance with the invention will be explained referring to FIGS. 5-7. The elements in the first embodiment are assigned the same reference numbers and will not be described, in the explanation below. The difference between the first and the second embodiments is that the KNbO₃ single crystal thin film 10 of the first embodiment is manufactured, with the KNbO₃ single crystal grown epitaxially on the SrTiO₃ single crystal substrate 11 by a liquid drop emission method, while in the second embodiment, a substrate 30, which comprises a silicon single crystal substrate 30a and a buffer layer 31 grown epitaxially thereon by a vapor deposition method, has a KNbO₃ single crystal layer 12 epitxially grown thereon by a liquid drop emission method, which leads to manufacturing the KNbO₃ single crystal thin film 32.

The surface of the silicon single crystal substrate 30a is comprised of orthorhombic (100) orientation and coated with natural oxidation film. The buffer layer 31 comprises a first buffer layer 34 and a second buffer layer 35 epitaxially grown on the first buffer layer 34. The first buffer layer 34 contains a first buffer layer 34a having yttria-stabilized zirconia (YSZ) and a first buffer layer 34b having CeO₂ epitaxially grown on the first buffer layer 34a.

The first buffer layer 34a and the first buffer layer 34b are comprised of a metallic oxide, which may be a NaCl structure or fluorite structure. Especially, the following is preferable: MgO, CaO, SrO, or BaO that includes metal apt to combine with oxygen thermodynamically than Si, or at least one kind of solid solutions that include these, or YSZ, CeO₂, Zr O₂, or at least one kind of solid solutions that include these. In the embodiment, as the first buffer layer 34a, YSZ is epitaxially grown in cubic (100) orientation, and as the first buffer layer 34b, CeO₂ is epitaxially grown in cubic (100) orientation

The second buffer layer 35 is comprised of a second buffer layer 35a and a second buffer layer 35b. The second buffer layer 35a is made with YBa₂Cu₃Oₓ, laminated perovskite-type oxide, epitaxially grown in tetragonal or orthorhombic (100) orientation. The second buffer layer 35b is manufactured on the second buffer layer 35a with SrTiO₃, simple perovskite-type oxide, epitaxially grown in cubic (100) orientation. The KNbO₃ single crystal layer 12 is structured on the second buffer layer 35 in orthorhombic (110) or (001) orientation. When the first buffer layer 34 is manufactured using a metallic oxide of NaCl structure such as MgO, the same effect can be attained even if only SrTiO₃ as the second buffer layer 35 is epitaxially grown in cubic (100) orientation.

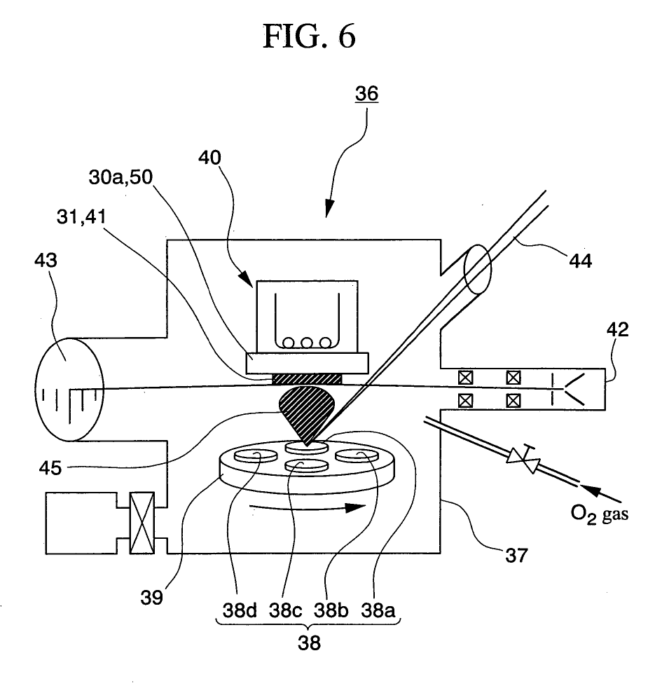

FIG. 6 is a perspective view of a deposition apparatus for the second embodiment. The buffer layer 31 is made by a vapor deposition method that accompanies ion beam radiation. In the embodiment, a thin film is formed by a pulsed laser deposition (PLD) method. A film forming apparatus 36, shown in FIG. 6, used for forming a film includes a process chamber 37, at least one workpiece 38 placed opposite to a single crystal substrate 30a, a workpiece support unit 39 that supports and rotates the workpiece 38 thereon and enables the workpiece 38 to revolve on its own axis, and a holding unit 40 for holding the single crystal substrate 30a. The film forming apparatus 36 contains a reflection high energy electron diffraction (RHEED) source 42 used for analyzing a thin film 41 in a RHEED method, and an RHEED screen 43 for detecting beams reflected by the thin film 41 that are emitted by the RHEED source 42 to the thin film 41 deposited on the silicon single crystal substrate 30a.

A PLD method, a film forming method, is described next. While a thin film is being formed, ArF or KrF excimer laser beams 44 are applied to the workpiece 38 rotating on its own axis in a pulse mode, with the inside of the process chamber 37 in an oxygen atmosphere of extremely low pressure, for example, 1/1000 of atmospheric pressure. The application of the laser beams brings the constituent of the workpiece into a plasma plume (plasma or molecular state) 45, which is caused to flow to the silicon single crystal board 30a to deposit the thin film 41.

Next, a description of a manufacturing method for the KNbO₃ single crystal thin film 32 will be made. The manufacturing method includes the following steps. After the buffer layer 31 is formed on the silicon single crystal substrate 30a by a PLD method, liquid drops of a water solution having KNbO₃ are coated on the buffer layer 31 by a liquid drop emission method, which is called a coating step. The orthorhombic potassium niobate single crystal is precipitated from the coated liquid drops by epitaxial growth, which is called a precipitating step. The manufacturing method will be explained below.

First, by the same procedure used for the first embodiment, a K₂NbO₃F aqueous solution 25 is prepared, for example, in the vicinity of supersaturation concentration. Next, a silicon single crystal substrate 30a is provided. The silicon single crystal substrate 30a is immersed in an organic solvent, and is degreased and cleaned using an ultrasonic cleaning apparatus. As an organic solvent, for example, a mixed liquid of alcohol and acetone in a ratio of 1:1 can be used. However, the present invention is not limited to the mixed liquid. To leave a natural oxidized film, the step to remove natural oxidized films such as RCA cleaning or fluoride cleaning, which is typical of cleaning silicon single crystal substrates, should not be carried out. The natural oxidized films can be confirmed, because diffraction patterns cannot be observed in a RHEED pattern from the Si<011> direction and restructured surfaces by Si(100)2×1 cannot be formed.

Manufacturing the buffer layer 31 will be explained by the film forming apparatus of FIG. 6 using the PLD method. First, the buffer layer 34 is formed on the silicon single crystal substrate 30a. The degreased and cleaned silicon single crystal substrate 30a is loaded on the holding unit 40, and then is brought into the process chamber 37, whose pressure is reduced to 1.33×10⁻⁶ Pa (1×10⁻⁸ Torr) and whose temperature is raised to 700° C. at the rate of 10° C./min. by infrared lamps (not shown). In the temperature region of more than 500° C., since part of natural oxidization film is evaporated as SiO, the level of the vacuum is raised to 1.33×10⁻⁴ Pa (1×10⁻⁶ Torr), but at 700° C. is below 6.65×10⁻⁵ Pa (5×10⁻⁷ Torr) and is constant. When a new thermal oxidation film is not manufactured on the surface of the silicon single crystal substrate 30a, the rate of temperature increase, substrate temperature, pressure, etc., are not limited to these.

When the pressure has become constant, the workpiece 38 having YSZ is placed opposite to the silicon single crystal substrate 30a, with a distance of more than 30 mm and less than 50 mm therebetween. On the condition that the substrate temperature is somewhere between 650 and 750° C., and oxygen pressure at the time of deposition is somewhere between 1.33×10⁻³ Pa (1×10⁻⁵ Torr) and 1.33×10⁻² Pa (1×10⁻⁴ Torr), excimer laser beams 44, whose energy density is more than 2 J/cm² and less than 3 J/cm² and whose frequency is more than 5 Hz and less than 15 Hz, are irradiated on the surface of the workpiece 38. The conditions are not limited to the above ranges, as long as Y and Zr plasmas are selectively produced at the substrate, and epitaxial growth can be carried out as YSZ removing natural oxidization film on the substrate as SiO. However, subject to a condition or conditions, even if the YSZ first buffer layer 34a is formed, a new oxidization film may be formed since oxygen is supplied to the boundary of the silicon single crystal substrate 30a. When ZrO₂ forms a solid solution as cubic, Y may be replaced by one of the following elements: La, Ce, Pr, Nd, Pm, Sm, Eu, Gd, Th, Dy, Ho, Er, Tm, Yb, Lu, Mg, Ca, Sr, and Ba.

Pulsed excimer laser beams 44, having energy density of 2.5 J/cm², frequency of 10 Hz, and a pulse width of 10 ns, are emitted to produce a plasma plume 45 comprising Y, Zr, and O on the surface of the workpiece 38. The plasma plume 45 is directed toward the silicon single crystal substrate 30a placed 40 mm away from the workpiece 38, for ten minutes at a substrate temperature of 700° C. and an oxygen pressure of 6.65×10⁻³ Pa (5×10⁻⁵ Torr), to grow the YSZ first buffer layer 34a epitaxially 5 nm, as shown in FIG. 5.

The forming of the first buffer layer 34b is explained below. The workpiece support unit 39 is rotated so that the workpiece 38b including CeO₂ may be placed in opposition to the silicon single crystal substrate 30. The pulsed KrF excimer laser beams 44 are irradiated on the surface of the workpiece 38b, as mentioned above. The illumination conditions are the same as those of YSZ. At this time, laser energy density of 2.5 J/cm², frequency of 10 Hz, and a pulse width of 10 ns are set. Plasma plume 45 containing Ce and O is generated on the surface of the workpiece 38b. The plasma plume is illuminated to the silicon single crystal substrate 30a placed 40 mm away from the workpiece 38b, for ten minutes at the substrate temperature of 700° C. and oxygen pressure of 6.65×10³ Pa (5×10⁻⁵ Torr), to grow the CeO₂ first buffer layer 34b epitaxially 10 nm, as shown in FIG. 5. As long as CeO₂ is grown epitaxially, the conditions such as temperature are not limited to the above. If CeO₂ constitutes a solid solution as cubic, the same effect can be obtained when Pr or Zr is added.

Next, formation of the second buffer layer 35a will be described. The workpiece support unit 39 is rotated so that the workpiece 38c including YBa₂Cu₃Oₓ may be placed opposite to the silicon single crystal substrate 30. The pulsed KrF excimer laser beams 44 are irradiated on the surface of the workpiece 38c, as mentioned above. The substrate temperature is somewhere between 550 and 650° C., and the oxygen pressure at the time of deposition is somewhere between 1.33×10⁻¹ Pa (1×10⁻³ Torr) and 1.33×10¹ Pa (1×10⁻¹ Torr). Except for these conditions of the substrate temperature and the oxygen pressure, other conditions are the same as those of YSZ. The conditions of the laser beams are that the energy density is 2.5 J/cm², the frequency is 10 Hz, and the pulse width is 10 ns. Plasma plume 45 containing Y, Ba, Cu, and O is generated on the surface of the workpiece 38c. The plasma plume 45 is directed to the silicon single crystal substrate 30a placed 40 mm away from the workpiece 38c, for two minutes at the substrate temperature of 600° C. and oxygen pressure of 1.33 Pa (1×10⁻² Torr), to grow the YBa₂Cu₃Oₓ second buffer layer 35a epitaxially 2 nm, as shown in FIG. 5.

However, the conditions are not limited by the above as long as the plasma having Y, Ba, and Cu can reach the substrate at the ratio of 1:2:3 and the YBa₂Cu₃Oₓ is grown epitaxially. In addition, instead of YBa₂Cu₃Oₓ, the same effects can be obtained by a solid solution of M₂RuO₄ (M represents one of Ca, Sr, and Ba), RE₂NiO₄ (RE represents one of La, Ce, Pr, Nd, Pm, Sm, Eu, Gd, Th, Dy, Ho, Er, Tm, Yb, Lu, and Y) and NiO, REBa₂Cu₃Oₓ (RE represents one of La, Ce, Pr, Nd, Pm, Sm, Eu, Gd, Th, Dy, Ho, Er, Tm, Yb, and Lu), or (Bi, RE)₄Ti₃O₁₂ (RE represents one of La, Ce, Pr, Nd, Pm, Sm, Eu, Gd, Tb, Dy, Ho, Er, Tm, Yb, Lu, and Y).

The production of the second buffer layer 35b will be explained below. The workpiece support unit 39 is rotated so that the workpiece 38d including SrTiO₃ may be placed opposite to the silicon single crystal substrate 30. The pulsed KrF excimer laser beams 44 are irradiated to the surface of the workpiece 38d. The substrate temperature is somewhere between 550 and 650° C., and the oxygen pressure at the time of deposition is somewhere between 1.33×10⁻¹ Pa (1×10⁻³ Torr) and 1.33×10¹ Pa (1×10⁻¹ Torr), except that other conditions are the same as those of YSZ. The conditions on the laser beams are that the energy density is 2.5 J/cm², the frequency is 10 Hz, and the pulse width is 10 ns. Plasma plume 45 containing Sr, Ti, and O is generated on the surface of the workpiece 38d. The plasma plume 45 is irradiated to the silicon single crystal substrate 30a placed 40 mm away from the workpiece 38d, for 30 minutes at the substrate temperature of 600° C. and oxygen pressure of 1.33 Pa (1×10⁻² Torr), to grow the SrTiO₃ second buffer layer 35b epitaxially 100 nm, as shown in FIG. 5.

However, the conditions are not limited by the above, as long as the Sr and Ti plasma can reach the silicon single crystal substrate 30a at a 1:1 ratio and the SrTiO₃ can be grown epitaxially. In addition, instead of SrTiO₃, the same effects can be obtained by MTiO₃ (M is one of Ca and Ba), REAlO₃ (RE is one of La, Ce, Pr, Nd, Pm, Sm, Eu, Gd, Th, Dy, Ho, Er, Tm, Yb, Lu, and Y), MAlO₃ (M is one of Mg, Ca, Sr, and Ba), or REGaO₃ (RE is one of La, Ce, Pr, Nd, Pm, Sm, Eu, Gd, Th, Dy, Ho, Er, Tm, Yb, Lu, and Y).

The KNbO₃ single crystal layer 12 is grown epitaxially on the buffer layer 31 formed by a liquid drop emission method as is used for the first embodiment. In this way, if KNbO₃, SrTiO₃, YBa₂Cu₃Oₓ, CeO₂, YSZ, and Si are represented, respectively, by an index for an orthorhombic crystal, a cubic crystal, a tetragonal crystal, a cubic crystal, a cubic crystal, and a cubic crystal, the KNbO₃ single crystal thin film 32 obtained has the following orientation relationships. In a direction perpendicular to the film surface KNbO₃ (001)/SrTiO₃(100)/YBa₂Cu₃Oₓ(001)/CeO₂(100)/YSZ(100)/Si(100), and in a direction in-plane to the film surface KNbO₃<110>//SrTiO₃<010>//YBa₂Cu₃Oₓ<100>//CeO₂<011>//YSZ<011>//Si<011>.

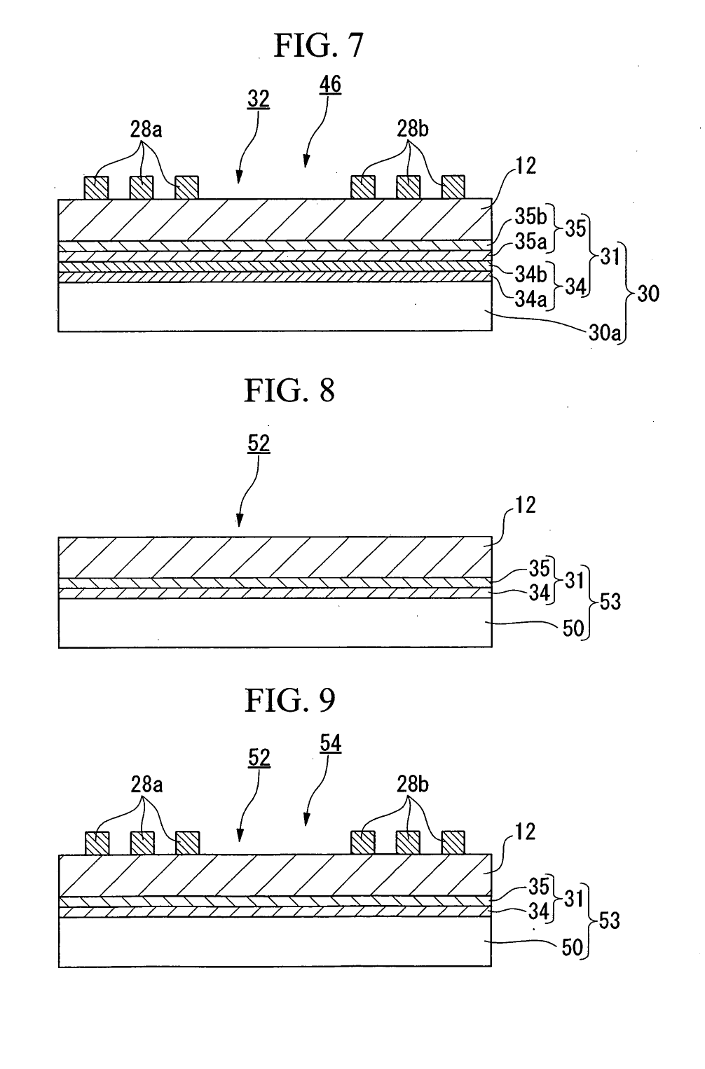

FIG. 7 is a cross-sectional view of a surface acoustic wave element of the second embodiment. A pair of IDTs 28a and 28b is formed on the KNbO₃ single crystal thin film 32 in the same way as is used for the first embodiment, which leads to manufacturing a surface acoustic wave element 46 shown in FIG. 7. The value of k² for the surface acoustic wave element manufactured in the embodiment is 25%, which is large enough. Even if an aqueous solution of niobium fluoride acid tantalic acid potassium sodium is used as a potassium niobate solution, solid solution film of K₁₋ₓNaₓNb_{1-y}Ta_{y}O₃ (0≦x≦1, 0≦y≦1) can be obtained as well. According to a method of manufacturing the KNbO₃ single crystal thin film, after forming the buffer layer 31 on the silicon single crystal substrate 30a, microscopic liquid drops of the K₂NbO₃F aqueous solution 25 are coated thereon. Therefore, the KNbO₃ single crystal thin film 32 can be produced at a low cost using inexpensive silicon single crystal substrates, and the surface acoustic element 46 having a large value of k² can be obtained from the KNbO₃ single crystal thin film 32.

The third embodiment in accordance with the invention will be described referring to FIGS. 8 and 9. The elements in the above embodiments are given the same reference numbers and will not be described, in the explanation below. The third embodiment differs from the second embodiment in that in the second embodiment the buffer layer 31 is made on the silicon single crystal substrate 30a and the KNbO₃ single crystal is grown epitaxially, while in the third embodiment on the crystal substrate (substrate itself) 50 is made the buffer layer 31, on which the KNbO₃ single crystal is grown epitaxially.

FIG. 8 is a cross-sectional view of KNbO₃ thin film in the third embodiment. A KNbO₃ single crystal thin film 52, as shown in FIG. 8, in the third embodiment includes a substrate 53 and a KNbO₃ single crystal layer 12 grown epitaxially thereon. The substrate 53 is comprised of a crystal substrate (substrate itself) 50 and a buffer layer 31 formed thereon. The material for the crystal substrate 50 may be quartz except for a crystal, silicon coated by SiO₂, or silicon coated by diamond. It may also be ceramics such as polycrystal YSZ substrate, or amorphous material such as glass substrate. In addition, it may be a perovskite-type oxide having crystal structure on which epitaxial growth cannot be obtained. In the embodiment, a crystal is used that is universal and important as a substrate for a surface acoustic wave element.

The buffer layer 31 includes a first buffer layer 34 and a second buffer layer 35 consisting of SrTiO₃, a simple perovskite-type oxide, grown epitaxially in cubic (100) orientation on the first buffer layer 34. The first buffer layer 34 is comprised of metal oxide. As examples for the metal oxide, metal oxide having NaCl structure or fluorite structure can be given. The following is preferred: MgO, CaO, SrO, or BaO that includes metal tending to combine with oxygen more thermodynamically than Si, or at least one kind of solid solution that include these; or YSZ, CeO₂, or Zr O₂, or at least one kind of solid solution that include these. In addition, in-plane orientation direction does not have to have any relationship with crystal orientation of the surface of the substrate.

The first buffer layer 34 of the embodiment is comprised of MgO that is NaCl-type oxide and grown in cubic (100) and in-plane orientation. When fluorite-type oxide such as YSZ or YSZ/CeO₂ is used in the first buffer layer 34, the following structure is grown epitaxially to be used. That is, as the second buffer layer 35, metal oxide of layered perovskite structure such as YBa₂Cu₃Oₓ is grown epitaxially in tetragonal or orthorhombic (001) orientation, on which SrTiO₃ is grown epitaxially in cubic (100) orientation. The KNbO₃ single crystal layer 12 is structured such that KNbO₃ single crystal may be in orthorhombic (110) or (001) orientation.

The method of manufacturing the KNbO₃ single crystal thin film 52 described above will be explained below following each step. First, by the same method as is employed in the first embodiment, a K₂NbO₃F aqueous solution near supersaturation is prepared. Next, a crystal substrate 50 is prepared. After the crystal substrate 50 is immersed in an organic solvent, an ultrasonic cleaning apparatus is used for degreasing and cleaning. As an organic solvent, for example, a mixed liquid of ethyl alcohol and acetone at the ratio of 1:1 can be used. However, the present invention is not limited to the mixed liquid.

Next, the buffer layer 31 is formed on the crystal substrate 50 by the film forming apparatus shown in FIG. 6. The first buffer layer 34 is formed on the crystal substrate 50. The degreased and cleaned crystal substrate 50 is loaded on the holding unit 40, and then is brought into the process chamber 37, into which a mixed gas is introduced so that the pressure 1.33×10⁻² Pa (1×10⁻⁴ Torr) may be established at a partial pressure ratio of Ar:Oxygen=100:1. The pressure condition is not limited to this.

When the pressure has become constant, the workpiece 38 having Mg or MgO is placed opposite to the crystal substrate 50a, with a distance of more than 30 mm and less than 50 mm therebetween. On the condition that the pressure at the time of deposition is somewhere between 1.33×10⁻³ Pa (1×10⁻⁵ Torr) and 1.33×10⁻² Pa (1×10⁻⁴ Torr), excimer laser beams, whose energy density is more than 2 J/cm² and less than 3 J/cm² and whose frequency is more than 5 Hz and less than 15 Hz, are irradiated to the surface of the workpiece 38a. If MgO is grown in in-plane orientation, the conditions are not so limited.

Pulsed KrF excimer laser beams 44, having an energy density of 2.5 J/cm², a frequency of 10 Hz, and a pulse width of 10 ns, are applied to the Mg workpiece 38a. On the surface of the workpiece 38a is produced the plasma plume 45 of Mg. The plasma plume 45 is irradiated to the crystal substrate 50 placed 40 mm away from the workpiece 38a, for ten minutes at a pressure of 1.33×10⁻² Pa (1×10⁻⁴ Torr), to grow the MgO first buffer layer 34 epitaxially 10 nm, as shown in FIG. 8.

Argon ion beams are impinging on the substrate at an angle of 45° with respect to a normal direction from the surface of the crystal substrate 50. As an ion beam source, a Kauffmann ion source is preferable. It is also preferable that an acceleration voltage for ion beams be 200 eV, and that a current be 10 mA. The substrate temperature does not control the temperature of a heater; however, impact by the argon ion beams raises the temperature of the substrate to 50-70° C.

After the MgO first buffer layer 34 is deposited, the SrTiO₃ second buffer layer 35 is grown epitaxially by 10 nm by the same method as is used in the second embodiment. Argon ion beams are irradiated on the substrate, in the same conditions as the above, at an angle of 45° with respect to a normal direction from the surface of the crystal substrate 50, which produces a substrate 53. On the buffer layer 31 of the substrate 53, the KNbO₃ single crystal layer 12 is grown epitaxially by a liquid drop emission method used for the first embodiment. In this way, when KNbO₃, MgO, and SrTiO₃ are represented, respectively, by an orthorhombic, cubic, or cubic crystal index, the KNbO₃ single crystal thin film 52 is produced that has the following orientation relationship: in the direction perpendicular to the film surface, KNbO₃(001)/SrTiO₃(100)/MgO(100); and in the direction in-plane to the film surface, KNbO₃<110>//SrTiO₃<010>//MgO<010>.

On the KNbO₃ single crystal thin film 52, a pair of IDTs 28a and 28b are formed by the same method as in the first embodiment, which makes a surface acoustic wave element 54 of the present embodiment shown in FIG. 9. As a result, the value k² of the surface acoustic wave element 54 of the present embodiment is 25%, which is large enough. Even if an aqueous solution of potassium sodium niobate tantalate fluoride (K₁₋ₓNaₓ)₂(Nb_{1-y}Ta_{y})O₃F(0≦x≦1, 0≦y≦1) is used as a potassium niobate solution, solid solution film of K₁₋ₓNaₓNb_{1-y}Ta_{y}O₃ (0≦x≦1, 0≦y≦1) can be obtained as well. According to a method of manufacturing the KNbO₃ single crystal thin film, even on the substrate comprising crystal that is important as a substrate for surface acoustic wave elements, microscopic liquid drops of the K₂NbO₃F aqueous solution 25 are coated. Therefore, the KNbO₃ single crystal thin film 52 can be produced. From the KNbO₃ single crystal thin film 52, the surface acoustic wave element 54 having a large value of k² is obtained at a low cost.

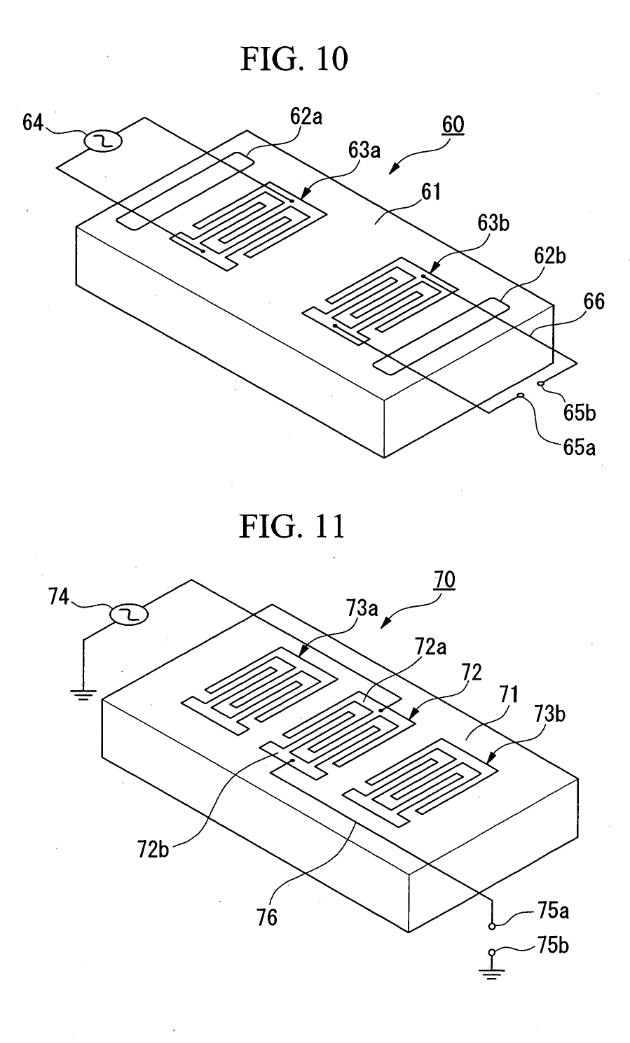

A frequency filter will be explained that includes a surface acoustic wave element in accordance with the invention. FIG. 10 is a perspective view of a frequency filter 60 of the embodiment in accordance with the invention. The frequency filter 60 comprises a surface acoustic wave element 61 including one of the KNbO₃ single crystal thin films 10, 32, and 52, and a pair of sound absorbing units 62a and 62b absorbing a train of surface acoustic waves that travels on the surface of the surface acoustic wave element 61. A pair of IDT electrodes 63a and 63b is formed on the surface acoustic wave element 61. The IDT electrodes 63a and 63b, formed from an Al or Al alloy, are set to about 1/100 in thickness of the pitch of the IDT electrodes. The IDT electrode 63a is connected to a high frequency signal source 64, while the IDT electrode 63b is coupled to signal line 65 including terminals 65a and 65b. The sound absorbing units 62a and 62b are formed so that they may sandwich the IDT electrodes 63a and 63b.

In the frequency filter 60, when a high frequency signal is output from the high frequency signal source 64, the frequency signal is applied to the IDT electrode 63a to generate a surface acoustic wave on the surface of the surface acoustic wave element 61. This surface acoustic wave propagates along the surface of the surface acoustic wave element 61 at a velocity of about 4,000 m/s. Of the surface acoustic wave, the one that has propagated from the IDT electrode 63a towards the sound absorbing unit 62a is absorbed by the sound absorbing unit 62a. But among the surface acoustic waves that have propagated towards the IDT 63b, a surface acoustic wave having a particular frequency determined by the pitch of the IDT 63b or having a frequency in a particular band is converted into an electric signal. The rest mostly pass the IDT 63b and are absorbed by the sound absorbing unit 62b.

According to the frequency filter 60, among the electric signals supplied to the IDT 63a, only a surface acoustic wave having a particular frequency or having a frequency in a particular band can be obtained with a high efficiency (filtering).

FIG. 11 is a perspective view of a frequency oscillator 70 of the embodiment in accordance with the invention. The frequency oscillator 70 includes a surface acoustic wave element 71 comprising one of the KNbO₃ single crystal thin films 10, 32, and 52. An IDT 72 and a pair of IDTs 73a and 73b that sandwiches the IDT 72 are formed on the surface of the surface acoustic wave element 71. The IDT 72 and IDTs 73a and 73b, made of an aluminum or aluminum alloy, are set at 1/100 in thickness of the IDT pitch. The IDT 72 further contains a pair of comb electrodes 72a and 72b. The electrode 72a is connected to a high frequency signal source 74, while electrode 72b is connected to a signal line 76 having terminals 75a and 75b.

In the frequency oscillator 70, when a high frequency signal is output from the high frequency signal source 74, the frequency signal is applied to the electrode 72a. On the surface of the surface acoustic wave element 71, a surface acoustic wave is generated that propagates to the IDT electrode 73a and the IDT electrode 73b, respectively. The velocity of the surface acoustic waves is about 4,000 m/s. Among the surface acoustic waves, a surface acoustic wave having a particular frequency component is reflected at the IDT electrodes 73a and 73b to generate a standing wave between the IDT electrode 73a and the IDT electrode 73b. Of the standing waves, a particular frequency component resonates to increase the amplitude. A part of the surface acoustic wave having this particular frequency component or the frequency component having a particular band is extracted from the comb electrode 72b; on the other hand, an electric signal having a frequency dependent on the resonance frequency (or a frequency having a certain band width) of the IDT electrodes 73a and 73b can be extracted at the terminals 75a and 75b.

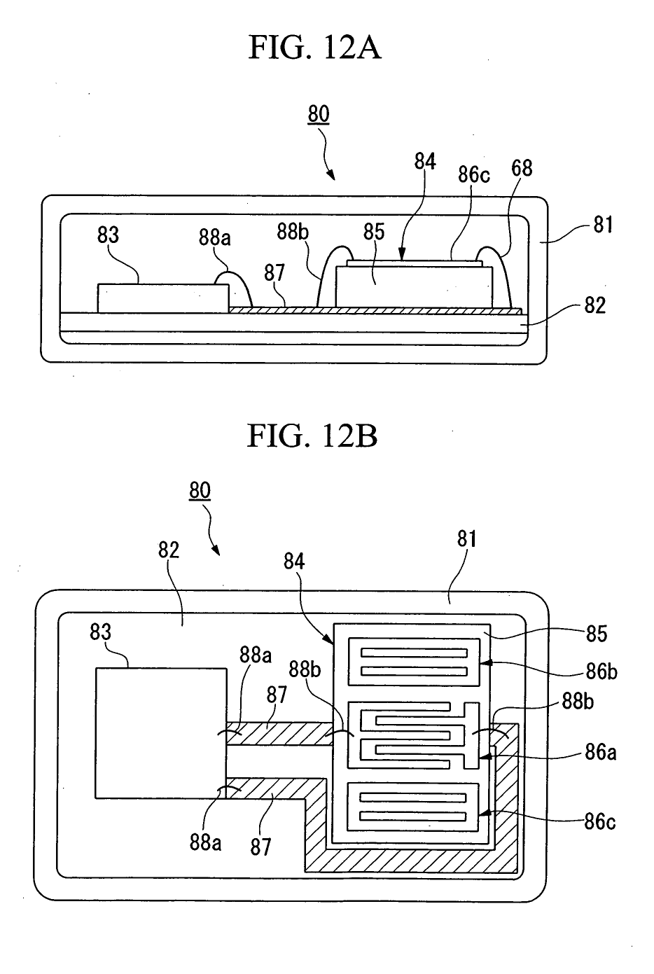

FIGS. 12A and 12B are a perspective view of a frequency oscillator of an embodiment in accordance with the invention. Those figures show one example in which the frequency oscillator 70 is applied to a VCSO (Voltage Controlled SAW Oscillator) 80. The VCSO 80 has a metal (aluminum and stainless steel) case 81 mounted therein, and the IC (integrated circuit) 83 and the frequency oscillator 84 mounted on the SAW substrate 82. The IC 83 controls the frequency applied to the frequency oscillator 84 in response to a voltage from an external circuit (not shown). The frequency oscillator 84 has a surface acoustic wave element 85, on which IDTs 86a, 86b and 86c are formed. On the SAW substrate 82, a wire pattern 87 is formed that electrically connects the IC 83 with the frequency oscillator 84. The IC 83 and the wire pattern 87 are electrically connected by wire leads 88a and 88b such as gold leads.

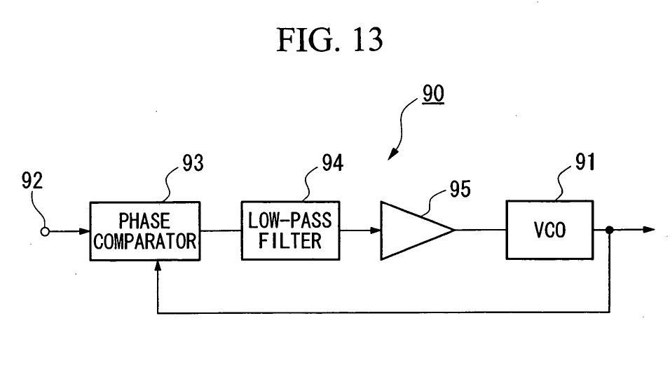

FIG. 13 is a block diagram showing a PLL (Phase Locke Loop) circuit of the embodiment in accordance with the invention. The VCSO 80 is used as a VCO (Voltage Controlled Oscillator) 91 for the PLL circuit 90 shown in FIG. 13. In addition to the VCO 91, the PPL circuit 90 comprises an input terminal 92, a phase comparator 93, a low-pass filter 94, and an amplifier 95. The phase comparator 93 compares the phase (or frequency) of a signal input from the input terminal 92 with that of the output signal from the VCO 91, to output an error voltage signal in response to the difference therebetween. The low-pass filter 94 passes only the low frequency components of the error electric signal from the phase comparator 93. The amplifier 95 amplifies the signal from the low-pass filter 94. The VCO 91 is an oscillation circuit where the oscillating frequency varies continuously within a range in response to the input applied thereto.

The PPL circuit 90 acts such that the difference between the phase (or frequency) from the input terminal 92 and that from the VCO 91 may be reduced. That is, when the frequency of the signal output from the VCO 91 is synchronized with the frequency of the signal input from the input terminal 92, the VCO 91 subsequently matches the frequency of the signal from the input terminal 92 except for a certain phase difference, thus following a variation of the input signal. Since the frequency oscillator 70 includes any one of the KNbO₃ single crystal thin films 10, 32, and 52, it can be small and inexpensive, and in addition produce filter characteristics that may handle a wide range of signals.

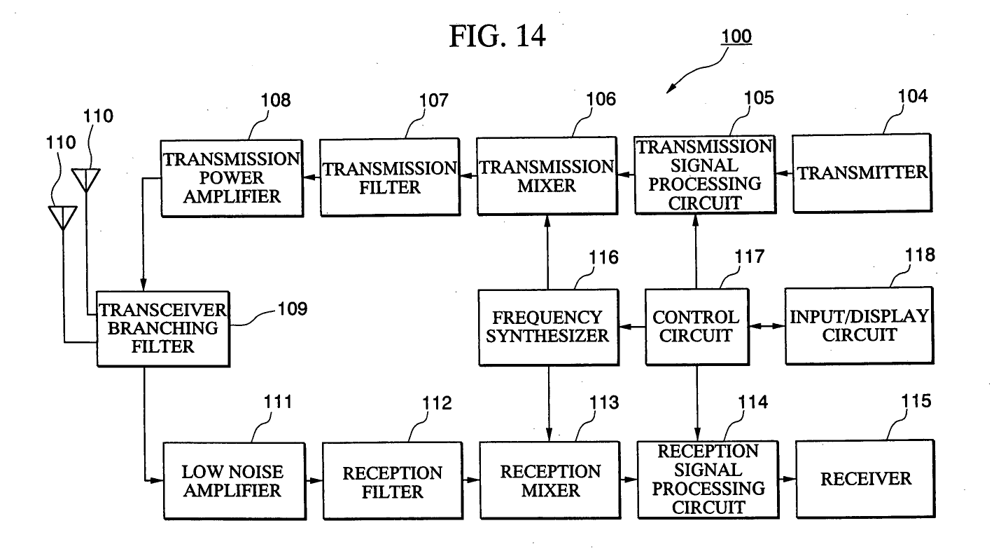

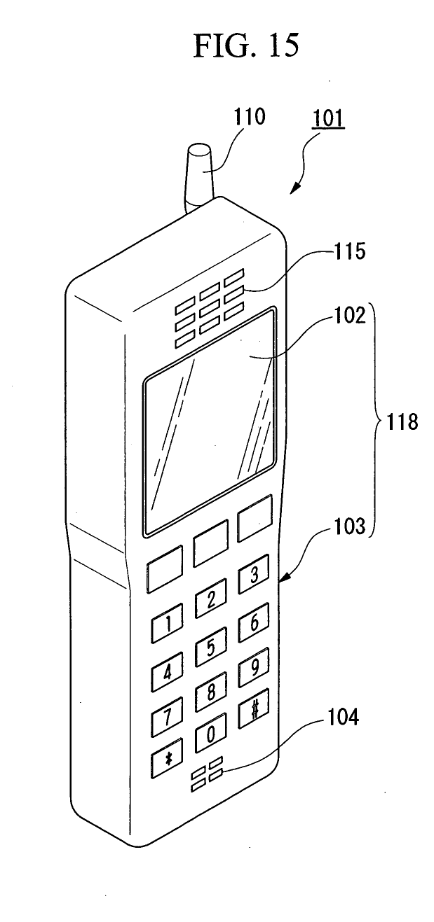

FIG. 14 is a block diagram showing an electronic circuit 100 of the embodiment in accordance with the invention. The electronic circuit 100, which includes the frequency filter 60 and the frequency oscillator 70, will be described below. The electronic circuit 100 is mounted in a mobile telephone (electronic device) 101 shown in FIG. 15. The mobile telephone 101 has a liquid crystal display 102 and operation buttons 103. The electronic circuit 100 comprise a transmitter 104, a transmission signal processing circuit 105, a transmission mixer 106, a transmission filter 107, a transmission power amplifier 108, a transceiver branching filter 109, antennas 110, a low noise amplifier 111 a reception filter 112, a reception mixer 113, a reception signal processing circuit 114, a receiver 115, a frequency synthesizer 116, a control circuit 117, and an input/display circuit 118.

The transmitter 104 may be a microphone that converts a sound signal to an electric signal. The transmission signal processing circuit 105 performs D/A conversion process and modulation process in response to an electric signal from the transmitter 104.

The transmission mixer 106 mixes a signal from the transmission signal processing circuit 105 using a signal from the frequency synthesizer 116. The transmission filter 107, which corresponds to the frequency filter 60 of FIG. 10, may only pass a signal having necessary frequencies out of intermediate frequencies (IF) and cut off other unnecessary frequencies. The signal passed is converted to an RF signal by a conversion circuit (not shown). The transmission power amplifier 108 amplifies the RF signal for outputting to the transceiver branching filter 109. The transceiver branching filter 109 transmits the amplified RF signal through the antenna 110, and receives a signal from the antenna 110 to output to the low noise amplifier 111.

The low noise amplifier 111 amplifies an input signal that is output to a conversion circuit (not shown), where the signal is converted to the IF. The reception filter 112, which corresponds to the frequency filter 60 of FIG. 10, passes only signals having the required frequency among the IF and stops the signals having unnecessary frequencies. The reception mixer 113 mixes the signal from the reception filter 112 using a signal from the frequency synthesizer 116. The reception signal processing circuit 114 performs D/A conversion processing and demodulation processing of the signal from the reception mixer 113. The receiver 115 includes a small speaker that converts an electric signal to a sound signal.

The frequency synthesizer 116, which contains the PLL circuit 90 of FIG. 13, divides the signal from the PLL circuit 90 to generate signals to be supplied to the transmission mixer 106 and the reception mixer 113, and further divides part of the signal to produce a signal to be applied to the reception mixer 113. The signals are set independently by the transmission filter 107 and the reception filter 112. The input/display circuit 118 is provided for displaying the state of the mobile telephone 101 to a user, and for inputting the instructions by the user, which corresponds to the liquid crystal display 102 and the operation buttons 103 shown in FIG. 15. The control circuit 117 controls the transmission signal processing circuit 105, the reception signal processing circuit 114, the frequency synthesizer 11 6, and the input/display circuit 118, thus controlling the entire function of the mobile telephone 101. Since the electronic circuit 100 and the mobile phone 101 include any one of the KNbO₃ single crystal thin films 10, 32, and 52, they can be small, wideband, and economical in power consumption.

The scope of the invention is not limited to the embodiments described above, and various modification can be made without departing from the spirit of the invention. For example, the mobile phone 101 is described as an electronic device in the embodiments, and the electronic circuit 100 mounted in the mobile phone 101 is explained as an electronic circuit. However, the invention is not limited to the mobile phone, and can be applied to any mobile communication apparatus and electronic circuits mounted therein.

The invention can be applied not only to mobile telecommunication devices, but to communication devices that are used in a stationary state such as a tuner for receiving BS (Broadcast Satellite) or CS (Commercial Satellite) broadcast and electronic circuits provided therein. In addition, besides a communication device that uses electric waves propagating in the air as a communication carrier, the present invention can also be applied to an electronic device such as a HUB that uses a high frequency signal propagated in a coaxial cable or a light signal propagated in an optical cable, and electronic circuits provided therein.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A method of manufacturing potassium niobate single crystal thin film, comprising the steps of:
coating liquid drops of a potassium niobate solution on a substrate; and
precipitating orthorhombic potassium niobate single crystal from the liquid drops.

2. The method as defined in claim 1, wherein the step of coating liquid drops is carried out by a liquid drop emission method.

3. The method as defined in claim 2, wherein a volume of the liquid drop is less than 100 picoliters.

4. The method as defined in claim 1, wherein the coating step and the precipitating step are carried out repeatedly, and the coating is carried out so that the liquid drops to be coated in a subsequent step overlap with at least a part of the orthorhombic potassium niobate single crystal precipitated in a previous precipitating step.

5. The method as defined in claim 1, wherein the potassium niobate solution is a potassium niobate fluoride aqueous solution.

6. The method as defined in claim 1, wherein the substrate has a crystallographic axis on a surface thereof that is oriented in a direction perpendicular and in-plane to the surface, and the potassium niobate single crystal is epitaxially grown on the substrate.

7. The method as defined in claim 6, wherein the substrate is a strontium titanate (100) single crystal substrate.

8. The method as defined in claim 6, wherein the substrate comprises a silicon single crystal substrate and a buffer layer epitaxially grown thereon.

9. The method as defined in claim 8, wherein the buffer layer includes a first buffer layer having a NaCl-type oxide and a second buffer layer having a simple perovskite-type oxide epitaxially grown thereon.

10. The method as defined in claim 8, wherein the buffer layer includes a fluorite-type oxide first buffer layer, and a second buffer layer that contains a layered perovskite-type oxide epitaxially grown on the first buffer and a simple perovskite-type oxide epitaxially grown on the perovskite-type oxide.

11. The method as defined in claim 6, wherein the substrate includes one of a crystal, quartz,. SiO₂ covered silicon, and diamond-covered silicon, and a buffer layer formed thereon, and wherein the buffer layer includes a first buffer layer grown on the substrate in in-plane orientation independently of crystal orientation of a surface of the substrate and a second buffer layer having oxide epitaxially grown thereon, the first and second buffer layers manufactured by a vapor deposition method accompanying ion beam irradiation.

12. The method as defined in claim 11, wherein the first buffer layer is manufactured by a NaCl-type oxide, and the second buffer layer is manufactured by a simple perovskite-type oxide.

13. The method as defined in claim 11, wherein the first buffer layer is manufactured by a fluorite-type oxide, and wherein the second buffer layer is manufactured by a layered perovskite-type oxide and a simple perovskite-type oxide grown epitaxially thereon.

14. A surface acoustic wave element comprising a potassium niobate single crystal thin film produced by the manufacturing method as defined in claim 1.

15. A frequency filter comprising a surface acoustic wave element as defined in claim 14.

16. A frequency oscillator comprising a surface acoustic wave element as defined in claim 14.

17. An electronic circuit comprising a frequency oscillator as defined in claim 14.

18. An electronic apparatus comprising at least one of a frequency filter as defined in claim 15, a frequency oscillator as defined in claim 16, and an electronic circuit as defined in claim 1.
